(19) United States
(12) Patent Application Publication
(10) Pub. No.: US 2026/0221331 A1
(43) Pub. Date: Jul. 30, 2026

(54) INDUCTOR MODULE AND INVERTER MODULE COMPRISING SAME

(71) Applicant: LG INNOTEK CO., LTD., Seoul (KR)

(72) Inventors: Ji Hwan JEON, Seoul (KR); Jae Yeop JUNG, Seoul (KR); Tae Bok JUNG, Seoul (KR)

(21) Appl. No.: 19/145,662

(22) PCT Filed: Jan. 2, 2024
(86) PCT No.: PCT/KR2024/000055

§ 371 Date: Jul. 3, 2025

(30) Foreign Application Priority Data
Jan. 3, 2023 (KR) 10-2023-0000937
Dec. 29, 2023 (KR) 10-2023-0196604

(51) Int. Cl. H01F 27/28; H01F 27/02; H02M 7/00

(52) U.S. Cl. CPC H01F 27/28; H01F 27/02; H02M 7/003

(57) ABSTRACT

An inverter module, according to one embodiment of the present invention, comprises: a case that forms an internal space in which components are placed; a main heat sink that includes a heat dissipation plate coupled to a lower portion of the case and a main heat dissipation fin extending from the heat dissipation plate; and an inductor module that is bonded to a region of a lower region of the heat dissipation plate of the main heat sink on which the main heat dissipation fin is not formed, and has an inductor disposed in an internal space thereof, wherein the inductor module includes: a first accommodating part forming a first internal space accommodating a first inductor; a second accommodating part forming a second internal space accommodating a second inductor; and a heat dissipation fin extending from outer surfaces of the first accommodating part and the second accommodating part, wherein the first accommodating part and the second accommodating part are formed to be spaced apart from each other.

### TECHNICAL FIELD

The present invention relates to an inverter module, and more specifically, to an inverter module including an inductor module having a separate heat dissipation structure.

### BACKGROUND ART

Solar power generation is an eco-friendly energy generation method that replaces existing chemical power generation or nuclear power generation. Solar power generation includes a standalone type in which a battery is connected to a converter and a connection type in which it is connected to a power grid, and in general, standalone power generation consists of solar cells, storage cells, power conversion devices and the like, and power grid-connected systems are connected to commercial power so that load grid lines and power may be exchanged with each other.

The power generated by solar panels is difficult to use directly in homes or buildings and needs to be converted into usable power through power conversion devices such as inverters, but inverters generate a lot of heat during power conversion, and this heat may degrade performance, making heat dissipation crucial. Furthermore, sealing to prevent foreign substances from entering the inverter due to its external installation environment is also important. Many components are placed inside the inverter, and thus, the development of technology to efficiently arrange these components inside the inverter module is necessary.

### DETAILED DESCRIPTION OF THE INVENTION

### Technical Subject

The technical problem to be solved by the present invention is to provide an inverter module including an inductor module having a separate heat dissipation structure.

### Technical Solution

In order to solve the above technical problem, an inductor module according to one embodiment of the present invention comprises: a first inductor and a second inductor; a first accommodating part forming a first internal space accommodating the first inductor; and a second accommodating part forming a second internal space accommodating the second inductor, wherein the first accommodating part and the second accommodating part are formed to be spaced apart from each other.

In addition, the first accommodating part includes: a first base; and a first side plate being extended from the first base, wherein the second accommodating part includes: a second base; and a second side plate being extended from the second base, and wherein the length from the first base of the first accommodating part to an upper end of the first accommodating part may be longer than the length from the second base of the second accommodating part to an upper end of the second accommodating part.

In addition, the first inductor includes a plurality of coils, wherein the first base of the first accommodating part includes: a first coil seating portion on which some of the plurality of coils are disposed; and a second coil seating portion on which some of the remaining plurality of coils are disposed, and wherein the first coil seating portion and the second coil seating portion may be formed to be spaced apart from each other.

In addition, the first inductor may be disposed in the first accommodating part and molded, and the second inductor may be disposed in the second accommodating part and molded.

In addition, a first substrate being connected with the terminal of the first inductor and the lower portion is included, a first terminal block being disposed on an upper portion of the first substrate and connected to a first wire is included, and the first terminal block and the terminal of the first inductor may be electrically connected.

In addition, the first terminal block and a terminal of the first inductor may be electrically connected through a conductive pattern of the first substrate.

In addition, the first terminal block includes: a third base; a bolt accommodating part being extended from the center of the third base in a lower direction and coupled through the first substrate to form an internal space for accommodating a bolt; and a coupling part being extended from an edge of the third base in a lower direction and coupled with the first substrate, and wherein the first terminal block can be coupled with a ring terminal of the first wire being disposed on the third base through the bolt.

In addition, when the first inductor is disposed in the first accommodating part and molded, the first substrate is molded and the third base of the first terminal block may not be molded.

In addition, it includes a second substrate being connected with a terminal and a lower portion of the second inductor and a second terminal block being disposed in an upper portion of the second substrate to be connected to the second wire, wherein the second terminal block and a terminal of the second inductor may be electrically connected.

In addition, it includes: a wire discharge portion being extended from one side of a second side plate of the second accommodating part to form a passage through which a wire passes; and a first wire bracket being disposed on the wire discharge portion, wherein the first wire bracket may include: a fifth base in contact with a fourth base of the wire discharge portion; a first extension portion being extended obliquely from the fifth base and including a first through-hole through which at least one first wire electrically connected to the first inductor and at least one second wire electrically connected to the second inductor penetrate; and a second extension portion being extended from the first extension portion in parallel with the fifth base.

In addition, the first through-hole may include a plurality of first through-holes, each of the plurality of first through-holes including a first bushing portion including two holes spaced apart from each other.

In addition, the first inductor is an inverter-side inductor, and the second inductor may be a grid-side inductor.

In addition, the first inductor includes a plurality of coils, and may include a second wire bracket in a space between the first accommodating part and the second accommodating part, wherein the second wire bracket may include: a sixth base disposed in the space between the first accommodating part and the second accommodating part; a third side plate being extended from the sixth base; and a second through-hole through which a plurality of first wires, each electrically connected to each terminal of the plurality of coils, penetrate the third side plate adjacent to the first accommodating part among the third side plates.

In addition, the height of the third side plate adjacent to the first accommodating part among the third side plates may be higher than the height of the third side plate adjacent to the second accommodating part among the third side plates.

In addition, the second inductor may include a plurality of coils, and may include a third wire bracket in a space between the first accommodating part and the second accommodating part, wherein the third wire bracket may include: a seventh base being disposed in the space between the first accommodating part and the second accommodating part; a fourth side plate being extended from the seventh base; a third through-hole, in a fourth side plate among the fourth side plates adjacent to the second accommodating part, through which a plurality of second wires, each of which is electrically connected to each terminal of the plurality of coils, penetrate; and a fourth through-hole, in a fourth side plate among the fourth side plates adjacent to the first accommodating part, through which the plurality of second wires pass.

In addition, the height of the fourth side plate adjacent to the first accommodating part among the fourth side plates may be the same as the height of the fourth side plate adjacent to the second accommodating part among the fourth side plates.

In addition, it includes a wire discharge portion being extended from one side of the side plate of the first accommodating part to form a passage through which a wire passes; and a fourth wire bracket being disposed in the wire discharge portion, wherein the fourth wire bracket may include: a ninth base being in contact with the eighth base of the wire discharge portion; and a fifth side plate being extended from the ninth base and including a fifth through-hole through which at least one first wire electrically being connected to the first inductor and at least one second wire electrically being connected to the second inductor penetrate.

In addition, the first inductor includes a plurality of coils, wherein when the plurality of coils are disposed and molded in the first accommodating part, a portion of a plurality of first wires each electrically connected to each terminal of the plurality of coils is also molded, wherein at least a portion of each of the plurality of coils is exposed to the outside of the molding, and wherein the first wire passes between the coils being exposed to the outside of the molding and may be extended toward the second accommodating part.

In order to solve the above technical problem, an inverter module according to an embodiment of the present invention comprises: a case forming an internal space in which components are placed; a main heat sink including a heat dissipation plate being coupled to a lower portion of the case and a main heat dissipation fin being extended from the heat dissipation plate; and an inductor module being bond-coupled to a region of a lower region of the heat dissipation plate of the main heat sink not being formed with the main heat dissipation fin and disposed with an inductor in an internal space thereof, wherein the inductor module includes any one among the inductor modules.

In addition, the main heat dissipation plate includes a wire discharge portion from which a plurality of wires being electrically connected to the inductor module are discharged, wherein the plurality of wires being discharged from the wire discharge portion may be guided and discharged to positions corresponding to positions of connectors being respectively connected thereto.

### Advantageous Effects

According to embodiments of the present invention, heat dissipation performance for an inductor module can be improved. In addition, a wire being connected to an inverter module can be efficiently drawn into the case of the inverter module, and a plurality of discharged wires are guided to positions corresponding to positions of connectors being respectively connected thereto, so that workability can be improved when a worker performs a task of connecting wires whose positions are guided to connectors. Furthermore, workability is improved because the wall-mounting work of the inverter module becomes facilitated.

### BRIEF DESCRIPTION OF DRAWINGS

FIG. 1 is a perspective view of an inverter module according to an embodiment of the present invention.

FIG. 2 illustrates the inside of an inductor module according to an embodiment of the present invention.

FIG. 3 illustrates a heat dissipation fin of an inductor module according to an embodiment of the present invention.

FIG. 4 illustrates an inverter module according to an embodiment of the present invention.

FIG. 5 is a drawing for explaining a coupling slit of an inductor module being mounted on an inverter module according to an embodiment of the present invention.

FIGS. 6 to 10 are drawings for explaining a configuration in which an inverter module including an inductor module according to an embodiment of the present invention is coupled to an external bracket.

FIGS. 11 to 15 illustrate an inductor module according to another embodiment of the present invention.

FIGS. 16 and 17 are drawings for explaining a terminal block of an inductor module according to an embodiment of the present invention.

FIGS. 18 and 20 are drawings for explaining a wire bracket of an inductor module according to an embodiment of the present invention.

FIGS. 21 to 23 illustrate inductor modules according to another embodiment of the present invention.

FIGS. 24 to 26 illustrate inductor modules according to yet another embodiment of the present invention.

FIGS. 27 to 29 illustrate inductor modules according to still another embodiment of the present invention.

FIGS. 30 to 32 illustrate inductor modules according to still yet another embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention. In the present specification, the singular form may include the plural form unless specifically stated in the phrase, and when described as “at least one (or more than one) of a and b and c”, it may include one or more of all combinations that can be combined with a, b, and c.

In addition, in describing the components of the embodiment of the present invention, terms such as first, second, a, b, (a), and (b) may be used.

These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction with respect to one component may be included.

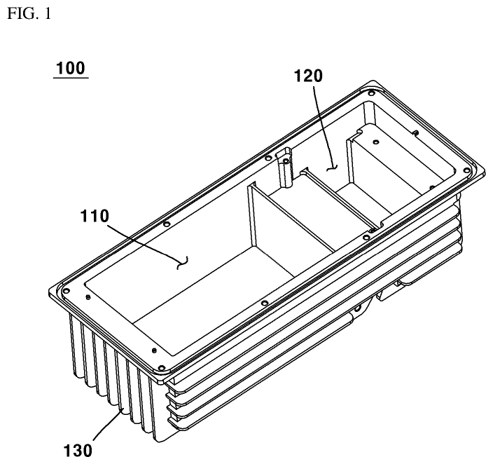

FIG. 1 is a perspective view of an inverter module according to an embodiment of the present invention.

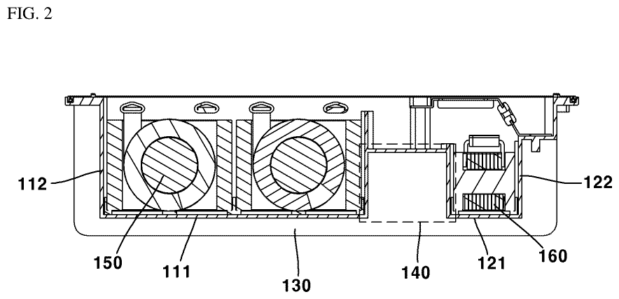

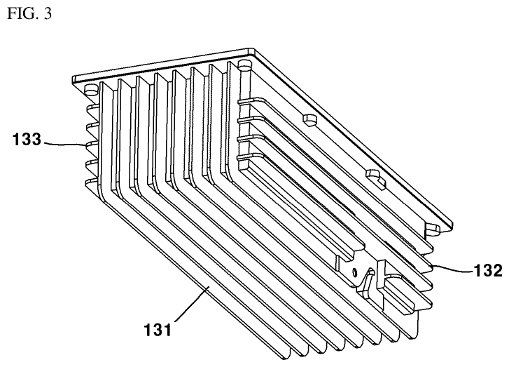

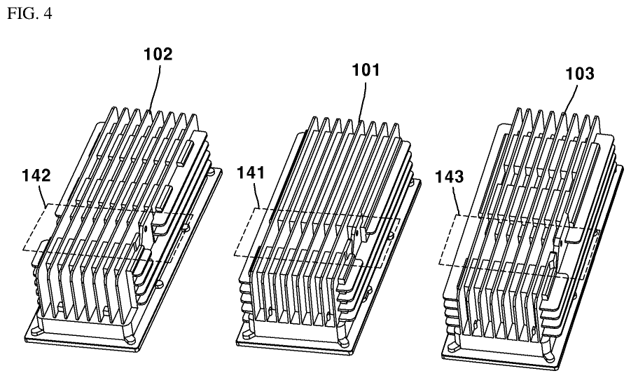

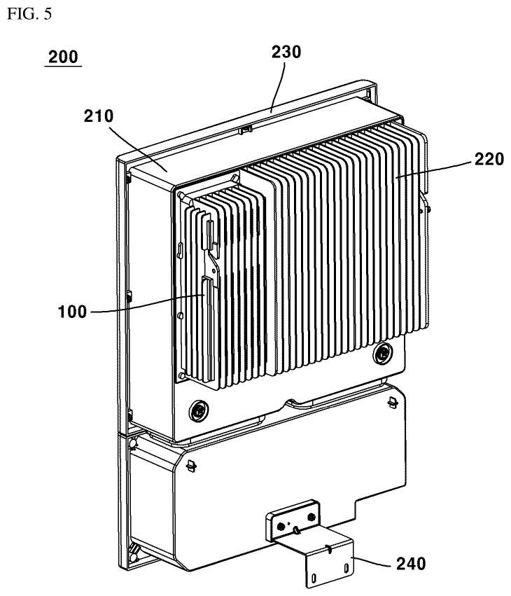

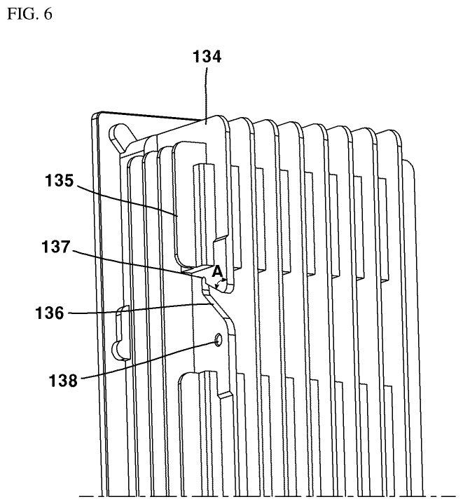

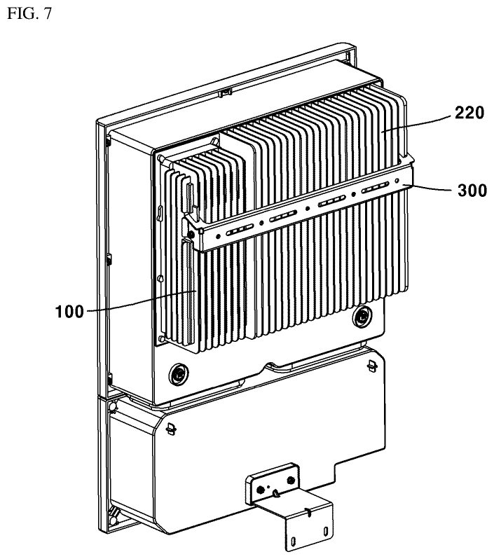

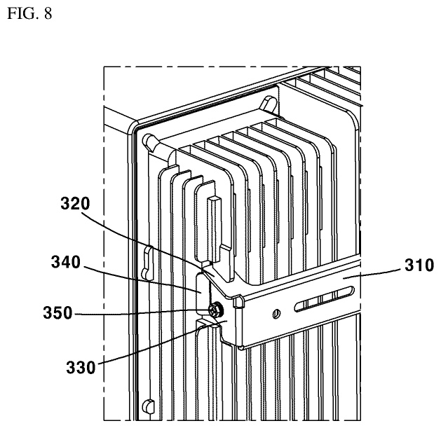

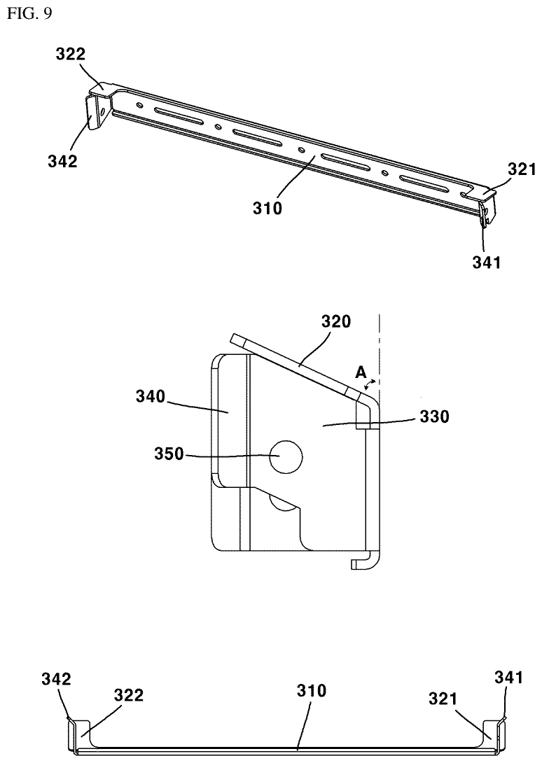

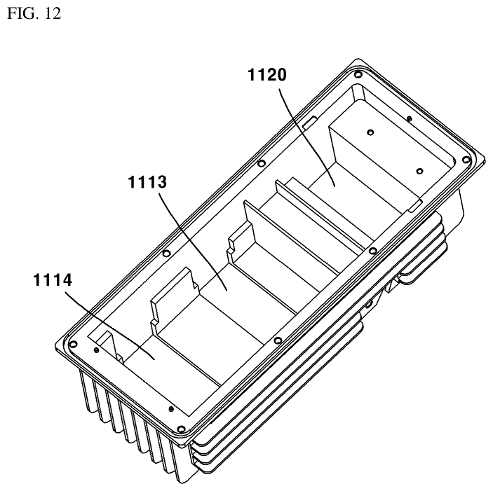

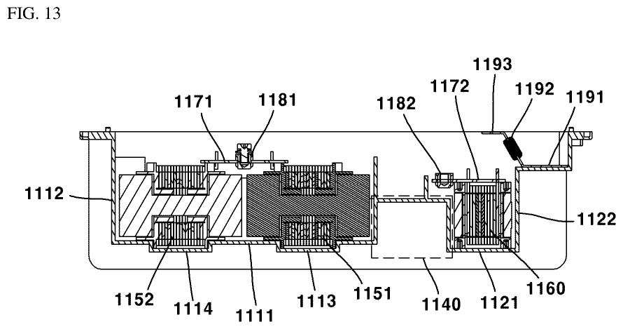

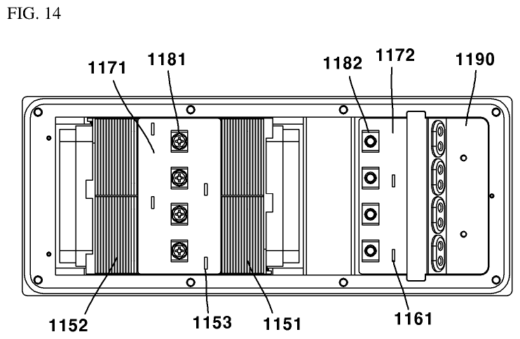

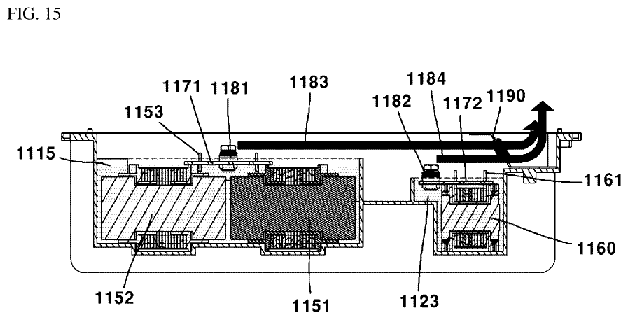

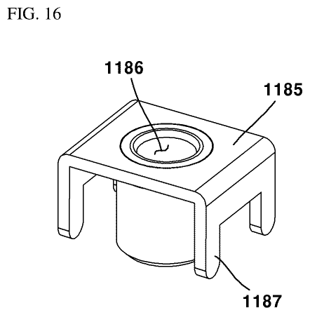

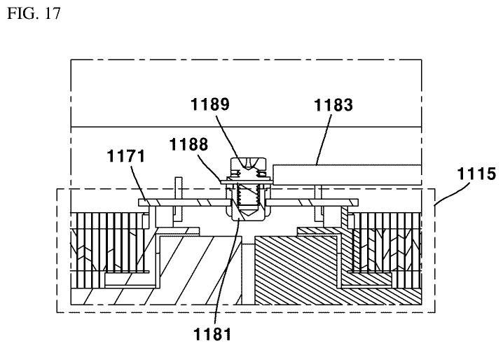

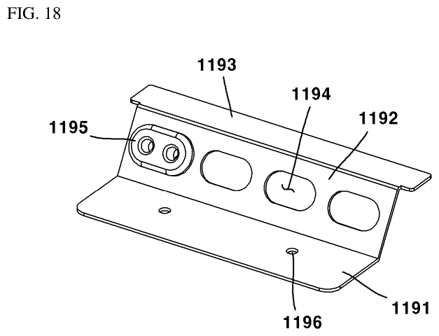

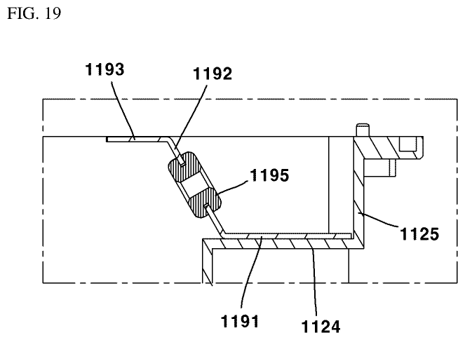

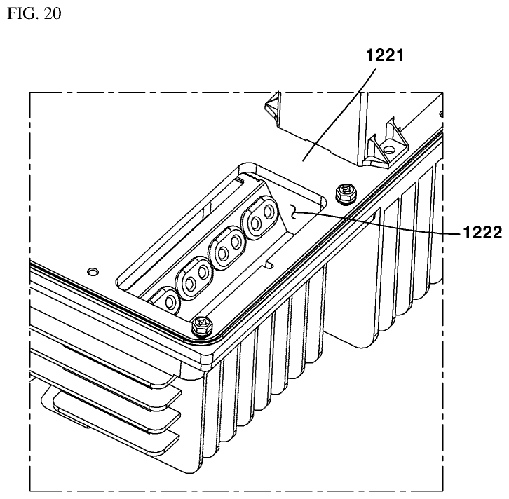

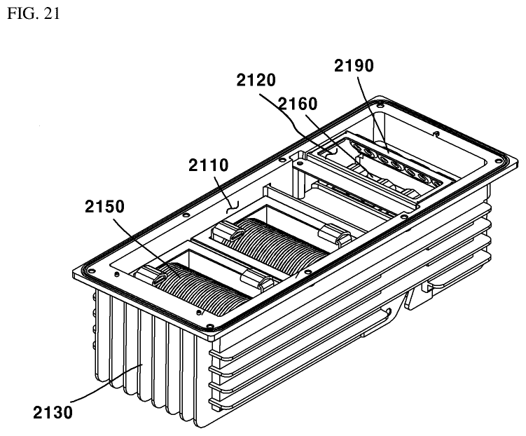

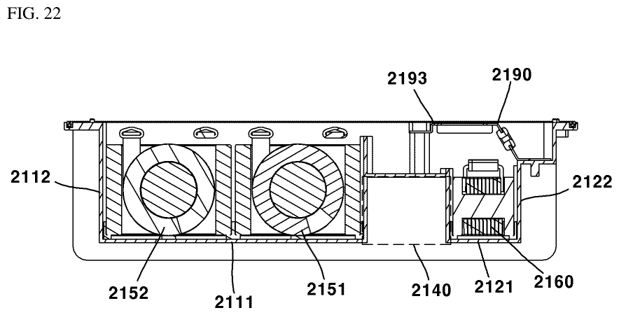

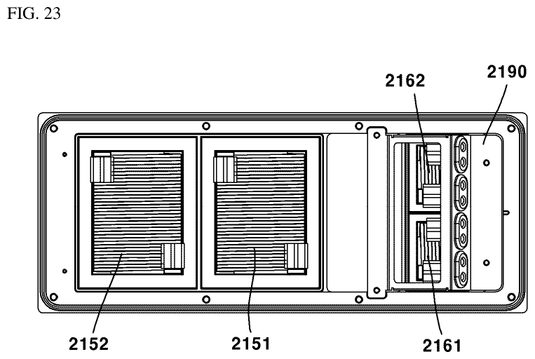

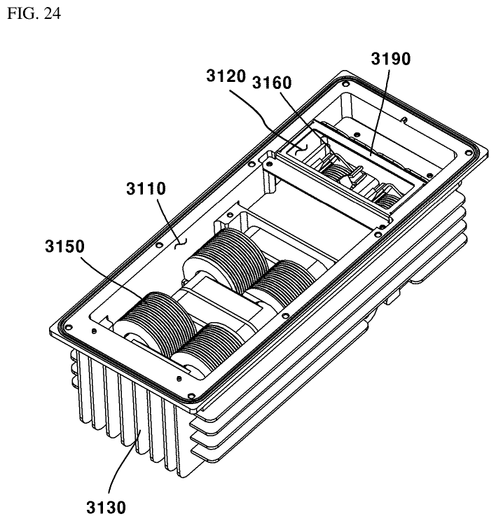

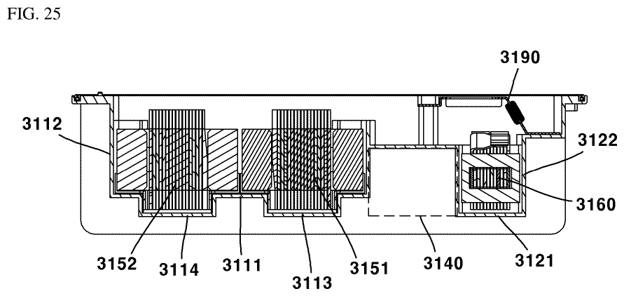

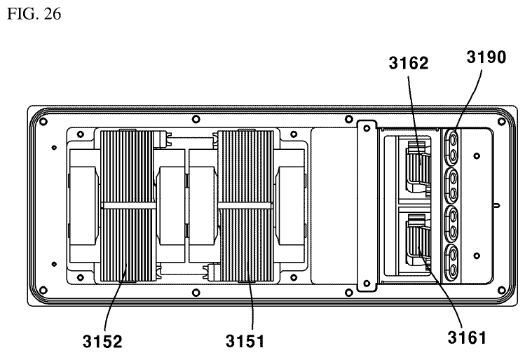

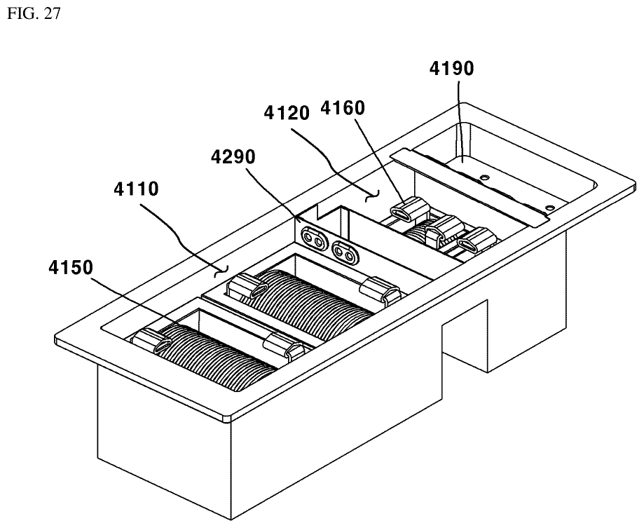

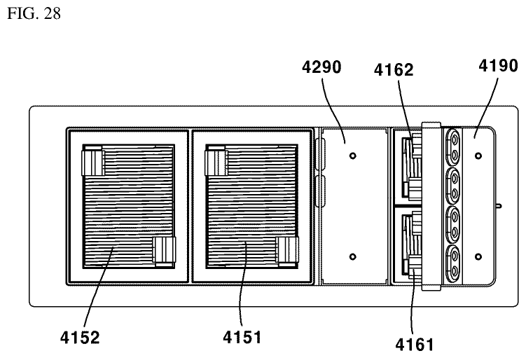

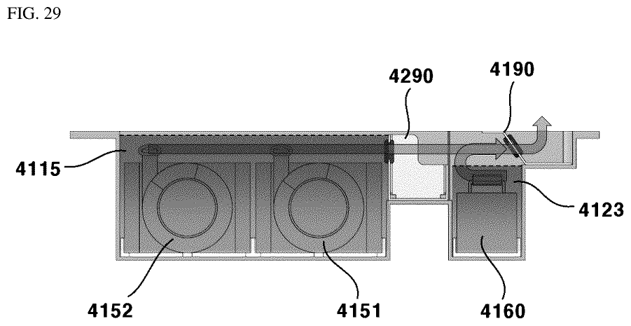

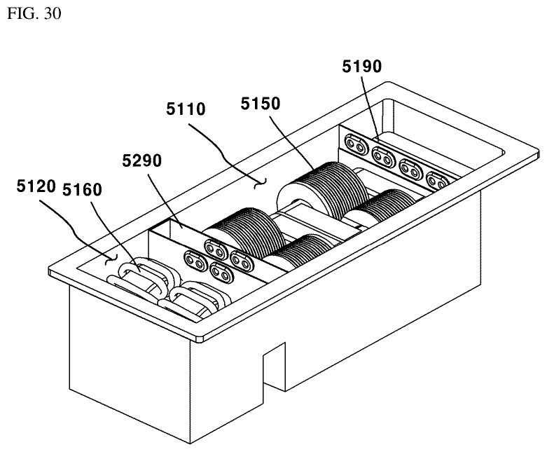

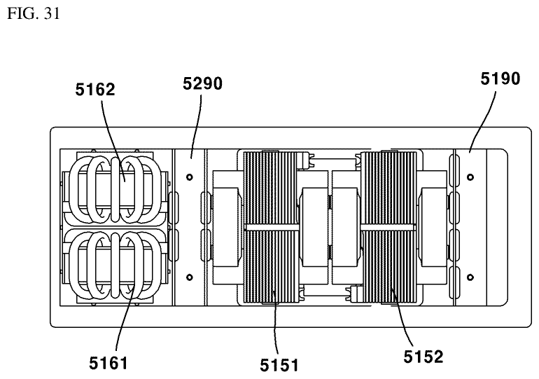

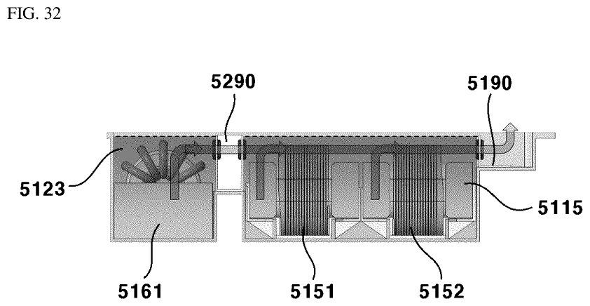

FIG. 2 illustrates the inside of an inductor module according to an embodiment of the present invention; FIG. 3 illustrates a heat dissipation fin of an inductor module according to an embodiment of the present invention; FIG. 4 illustrates an inverter module according to an embodiment of the present invention; FIG. 5 is a drawing for explaining a coupling slit of an inductor module being mounted on an inverter module according to an embodiment of the present invention; FIGS. 6 to 10 are drawings for explaining a configuration in which an inverter module including an inductor module according to an embodiment of the present invention is coupled to an external bracket; FIGS. 11 to 15 illustrate an inductor module according to another embodiment of the present invention; FIGS. 16 and 17 are drawings for explaining a terminal block of an inductor module according to an embodiment of the present invention; FIGS. 18 and 20 are drawings for explaining a wire bracket of an inductor module according to an embodiment of the present invention; FIGS. 21 to 23 illustrate inductor modules according to another embodiment of the present invention; FIGS. 24 to 26 illustrate inductor modules according to yet another embodiment of the present invention; FIGS. 27 to 29 illustrate inductor modules according to still another embodiment of the present invention; and FIGS. 30 to 32 illustrate inductor modules according to still yet another embodiment of the present invention.

An inductor module according to an embodiment of the present invention accommodates an inductor therein. An inverter module according to an embodiment of the present invention being mounted with an inductor module according to an embodiment of the present invention thereon may be a PV inverter module. A PV inverter module is a device that receives power from a PV panel or a PV converter and converts it into power that can be used in a home or a building, and receives dc power from a PV converter and the like to convert it into ac power and outputs it. At this time, the dc power is transmitted to an inverter driving unit through a wire connection unit, and the inverter driving unit converts the power, and then transmits the converted power to a load again through the wire connection unit. The inverter driving unit may include a power conversion element and a switching element or an MCU for controlling the power conversion element. The power conversion element may include a passive element such as an inductor or a capacitor, and may include a switching element implemented as a FET or a diode, and may include an MCU for controlling the switching element. In addition, various elements for converting power may be included, or elements for implementing functions other than power conversion may be included.

The inductor module according to an embodiment of the present invention can configure a separate module accommodating the inductor of the inverter module, thereby enabling efficient heat dissipation for the inductor that generates a lot of heat.

To this end, the inductor module according to an embodiment of the present invention accommodates an inductor therein and includes a first accommodating part 110, a second accommodating part 120, and a heat dissipation fin 130.

An inductor module according to an embodiment of the present invention accommodates a first inductor 150 and a second inductor 160. Here, the first inductor 150 may be an inverter-side inductor, and the second inductor 160 may be a grid-side inductor. The inverter-side inductor and the grid-side inductor may have different required specifications, and accordingly, the overall size of the inverter and the number of included coils may vary. In order to accommodate the first inductor 150 and the second inductor 160 in different spaces, the module includes a first accommodating part 110 for accommodating the first inductor 150 and a second accommodating part 120 for accommodating the second inductor 160.

The first accommodating part 110 forms a first internal space that accommodates a first inductor 150. The first accommodating part 110 may include a first base 111 and a first side plate 112 being extended from the first base 111. It may be configured with the first base 111 configuring a lower plate of the first accommodating part 110 and the first side plate 112 configuring a side plate of the first accommodating part 110, thereby accommodating the first inductor 150.

The second accommodating part 120 forms a second internal space that accommodates the second inductor 160. The second accommodating part 120 may include a second base 121 and a second side plate 122 being extended from the second base 121. The second accommodating part 120 may be configured with the second base 121 configuring a lower plate of the second accommodating part 120 and the second side plate 122 configuring a side plate of the second accommodating part 120, thereby accommodating the second inductor 160.

The first side plate 112 and the second side plate 122 in a direction in which the first accommodating part 110 and the second accommodating part 120 are facing each other may be spaced apart from each other, but may be connected to each other by a third base. The space between the first accommodating part 110 and the second accommodating part 120 may be formed by the third base and the first side plate 112 and the second side plate 122 in a direction in which the first accommodating part 110 and the second accommodating part 120 are facing each other.

The first accommodating part 110 and the second accommodating part 120 may be formed to be spaced apart from each other. The first inductor 150 being disposed in the first accommodating part 110 and the second inductor 160 being disposed in the second accommodating part 120 are different from each other as an inverter-side inductor and a grid-side inductor, and since magnetic fields being generated by the coils may affect each other, they may be disposed in different accommodating parts, and the first accommodating part 110 and the second accommodating part 120 may be spaced apart from each other so that they do not affect each other.

The sizes of the internal spaces being formed by the first accommodating part 110 and the second accommodating part 120 may be different. The internal space of the first accommodating part 110 may correspond to the size of the first inductor 150, and the internal space of the second accommodating part 120 may correspond to the size of the second inductor 160.

The first inductor 150 may have a larger size than the second inductor 160. The number of coils included in the first inductor 150 may be greater than the number of coils included in the second inductor 160, and the size of the coils included in the first inductor 150 may be larger than the size of the coils included in the second inductor 160.

Depending on the difference in size between the first inductor 150 and the second inductor 160, the size of the internal space of the first accommodating part 110 may be larger than the size of the internal space of the second accommodating part 120.

The length from the first base 111 of the first accommodating part 110 to the upper end of the first accommodating part may be longer than the length from the second base 121 of the second accommodating part 120 to the upper end of the second accommodating part. That is, the height of the internal space of the first accommodating part 110 may be greater than the height of the internal space of the second accommodating part 120. The area of the first accommodating part 110 may be wider than the area of the second accommodating part 120, and the internal volume of the first accommodating part 110 may be greater than the internal volume of the second accommodating part 120. The area of the first base 111 of the first accommodating part 110 may be wider than the area of the second base 121 of the second accommodating part 120. The length of the first base 111 in a first direction in which the first accommodating part 110 and the second accommodating part 120 are spaced apart may be longer than the length of the second base 121. In a direction perpendicular to the first direction in which the first accommodating part 110 and the second accommodating part 120 are spaced apart, the length of the first base 111 and the length of the second base 121 may be equal.

The first inductor 150 may be disposed and molded in the first accommodating part 110, and the second inductor 160 may be disposed and molded in the second accommodating part 120. After the first inductor 150 is disposed in the internal space of the first accommodating part 110, a molding liquid may be filled in the first accommodating part 110 to mold the first inductor 150. Through the molding, heat being generated in the first inductor 150 may be quickly and efficiently transferred to the first base 111 and the first side plate 112 of the first accommodating part 110. In addition, the first inductor 150 may be positioned in the first accommodating part 110 through the molding.

After the second inductor 160 is disposed inside the internal space of the second accommodating part 120, the molding liquid may be filled into the second accommodating part 120 to mold the second inductor 160. Through the molding, heat being generated in the second inductor 160 can be quickly and efficiently transferred to the second base 121 and the second side plate 122 of the second accommodating part 120. In addition, the second inductor 160 may be positioned in the second accommodating part 120 through the molding.

The heat dissipation fin 130 is extended from the outer surfaces of the first accommodating part 110 and the second accommodating part 120. The inductor module 100 according to an embodiment of the present invention is configured as a separate module that accommodates the inverter of the inverter module for efficient heat dissipation, and the heat dissipation fin 130 is formed on the outer surfaces of the first accommodating part 110 and the second accommodating part 120.

The heat dissipation fin 130 may comprise a plurality of first heat dissipation fins 131 formed along an outer surface of the first side plate 112 of the first accommodating part 110, an outer surface of the first base 111 of the first accommodating part 110, a space between the first accommodating part 110 and the second accommodating part 120, an outer surface of the second base 121 of the second accommodating part 120, and an outer surface of the second side plate 122 of the second accommodating part 120 along a first direction which is a lengthwise direction of the inductor module.

The first heat dissipation fin 131 may be formed to be extended over the entire outer surface of the inductor module 100 in a lengthwise direction of the inductor module. It may be formed along an outer surface of the first side plate 112 of the first accommodating part 110, an outer surface of the first base 111 of the first accommodating part 110, a separation space between the first accommodating part 110 and the second accommodating part 120, an outer surface of the second base 121 of the second accommodating part 120, and an outer surface of the second side plate 122 of the second accommodating part 120. The separation space between the first accommodating part 110 and the second accommodating part 120 is formed in a large area of heat dissipation fin, so that even if heat is transferred simultaneously from the first inductor 150 and the second inductor 160, heat dissipation to the outside can be efficiently achieved.

The heat dissipation fin 130 may include second heat dissipation fins 132 and 133 having a different extension direction from the first heat dissipation fin 131. The heat dissipation fin 130 may include a plurality of second heat dissipation fins 132 and 133 that are formed along an outer surface of a first side plate 112 of a first accommodating part 110 in which a first heat dissipation fin 131 is not formed along a first direction, a separation space between the first accommodating part 110 and the second accommodating part 120, and an outer surface of a second side plate 122 of the second accommodating part 120 in which the first heat dissipation fin 131 is not formed, and are spaced apart from each other in a third direction that is perpendicular to the first direction and the second direction. The first side plate 112 of the first accommodating part 110 in which the first heat dissipation fin 131 is not formed is formed of two side plates, and the second heat dissipation fins 132 and 133 may be formed by being extended in opposite directions from the two side plates facing each other.

The heat being generated in the first inductor 150 and the second inductor 160 can be dissipated to the outside through the first heat dissipation fin 131 and the second heat dissipation fins 132 and 133. Both the first heat dissipation fin 131 and the second heat dissipation fins 132 and 133 are formed to be extended in a first direction, and the first direction corresponds to an up and down direction when mounted on the inverter module, and heat can be efficiently dissipated by moving in an up and down direction.

The inductor module according to an embodiment of the present invention may be formed in various shapes (101, 102, and 103) as shown in FIG. 4, and heat dissipation can be efficiently achieved by forming the first accommodating part 110 and the second accommodating part 120 separately and spaced apart (141, 142, and 143).

An inverter module 200 according to an embodiment of the present invention includes a case 210 in which components are placed, a cover 230 covering the case 210, a main heat sink 220, and an inductor module 100. A detailed description of the inductor module 100 included in the inverter module 200 corresponds to the detailed description of the inductor module of FIGS. 1 to 4, and thus, any overlapping description will be briefly described hereinafter.

The case 210 forms an internal space in which components of an inverter module are disposed.

The inverter module 200 according to the embodiment of the present invention is implemented as one module through an inverter module case. The inverter module case is configured with an inverter driving unit and a wire connection unit as cases, respectively, and each case can be connected to each other to form one inverter module case. The inverter module case may be configured with a first case and a second case. The cover 230 may also include a first cover covering the first case and a second cover covering the second case. Or, it may be configured with one cover covering both the first case and the second case. The inverter driving unit is disposed inside the first case, and the wire connection unit is disposed inside the second case. Here, the second case in which the wire connection unit is disposed may be referred to as a wire connection module, and may be referred to as a wiring box or a junction box.

Here, the inverter driving unit may be a driving unit of a 7.6 kw inverter or an 11.4 kw inverter module. At this time, even if the types of inverters are different, by forming the horizontal length of the surface to be coupled with the wire connection unit to be the same, wire connection can be performed using a single wire connection module even if the types of inverters are different. That is, the wire connection module is applied in a detachable modular form with a common fastening structure, which enables the common structure for each product to reduce initial mold input costs and unify various lineups according to inverter types to form a family look.

The main heat sink 220 may include a heat dissipation plate being coupled to the lower portion of the case 210 and a main heat dissipation fin being extended from the heat dissipation plate. The main heat dissipation fin is attached to a plate-shaped heat dissipation plate in a lower portion of the case 210, that is, it may be attached to a plate-shaped heat dissipation plate at the lower portion of the case 210 where components are placed, and include a main heat dissipation fin being extended outward from a part of the region of the heat dissipation plate, so that heat being generated in the components can be discharged to the outside through the heat dissipation plate and the main heat dissipation fin. The main heat sink 220 may be configured with a material with high thermal conductivity.

The inductor module 100 is bond-coupled to a region at a lower portion of the heat dissipation plate of the main heat sink 220 where the main heat dissipation fin is not formed, and the inductor is disposed in an internal space. The inductor of the inverter module 200 is disposed in the inductor module 100 instead of inside the case 210, allowing for efficient heat dissipation. The inductor module 100 is in contact with the heat dissipation plate of the main heat sink 220 and includes a separate heat dissipation fin 130, allowing heat to be transferred not only in a direction where the heat dissipation fin 130 is formed but also in a direction of the heat dissipation plate, enabling efficient heat dissipation. The heat transferred from the inductor module 100 to the heat dissipation plate can be discharged to the outside through the main heat dissipation fin.

The inductor module 100 includes a first accommodating part 110 forming a first internal space for accommodating a first inductor 150, a second accommodating part 120 forming a second internal space for accommodating a second inductor 160, and a heat dissipation fin 130 being extended from outer surfaces of the first accommodating part 110 and the second accommodating part 120, and the first accommodating part 110 and the second accommodating part 120 are formed spaced apart from each other.

The first accommodating part 110 may include a first base 111 and a first side plate 112 being extended from the first base 111, and the second accommodating part 120 may include a second base 121 and a second side plate 122 being extended from the second base 121. The length from the first base 111 of the first accommodating part 110 to an upper end of the first accommodating part 110 may be longer than the length from the second base 121 of the second accommodating part 120 to an upper end of the second accommodating part 120.

The heat dissipation fin 130 may be formed along a first direction, which is the lengthwise direction of the inductor module 100, along an outer surface of the first side plate 112 of the first accommodating part 110, an outer surface of the first base 111 of the first accommodating part 110, a separation space between the first accommodating part 110 and the second accommodating part 120, an outer surface of the second base 121 of the second accommodating part 120, and an outer surface of the second side plate 122 of the second accommodating part 120, and may include a plurality of first heat dissipation fins 131 being spaced apart from each other in a second direction perpendicular to the first direction.

In addition, the heat dissipation fin 130 may be formed along the first direction, along an outer surface of the first side plate 112 of the first accommodating part 110 where the first heat dissipation fin 131 is not formed, a separation space between the first accommodating part 110 and the second accommodating part 120, and an outer surface of the second side plate 122 of the second accommodating part 120 where the first heat dissipation fin 131 is not formed, and may include a plurality of second heat dissipation fins 132 and 133 being spaced apart from each other in a third direction perpendicular to the first direction and the second direction. The first side plate 112 of the first accommodating part 110 where the first heat dissipation fin 131 is not formed may be two side plates, and the second heat dissipation fins 132 and 133 may be formed by being extended in opposite directions from two side plates facing each other.

The main heat dissipation fin of the main heat sink 220 may include a plurality of main heat dissipation fins being extended from the heat dissipation plate along a first direction and spaced apart from each other in a second direction perpendicular to the first direction.

Among the plurality of first heat dissipation fins, a first coupling slit 136 being coupled to an external bracket 300 may be formed on the outermost first heat dissipation fin farthest from the main heat dissipation fin. To install the inverter module 200 on the external bracket 300, workability can be improved by forming the first coupling slit on the outermost first heat dissipation fin 131. At this time, the first coupling slit 136 may be formed at a position corresponding to the separation space 140 between the first accommodating part 110 and the second accommodating part 120. Since the interior of the inductor module 100 is inwardly recessed in a separation space 140 between the first accommodating part 110 and the second accommodating part 120, a space for forming the first coupling slit is secured, thus allowing for space utilization by forming the first coupling slit 136 at a corresponding position. Since the weight of the inverter module 200 is applied to the outermost first heat dissipation fin 131, the thickness of the outermost first heat dissipation fin 131 may be reinforced to be thicker than the thickness of other heat dissipation fins.

In addition, among the plurality of second heat dissipation fins 132 and 133, the second heat dissipation fin 135 adjacent to the outermost first heat dissipation fin 134 may not have a heat dissipation fin formed in the separation space between the first accommodating part 110 and the second accommodating part 120. When coupled with the external bracket 300, an extension portion of the seating guide of the external bracket may be located at the position of the second heat dissipation fin 135, in which case a part of the second heat dissipation fin 135 may be removed. This allows for stable coupling with the external bracket 300.

The first coupling slit 136 may be formed inclined in a first direction towards a lower portion when the inverter module 200 is mounted on the external bracket 300, and may be formed in a tapered shape where the width of the slit widens. It may be formed inclined towards a lower portion so that it can receive force in a lower direction due to gravity when coupled with the external bracket 300. This allows for easier installation work by adding force in a coupling direction during the work, and can prevent the inverter module 200 from being detached after mounting.

At this time, the angle a inclined to a first direction of the first coupling slit 136 may be between 50 and 80 degrees, for example, 65 degrees. Or, it may be 45 degrees perpendicular to the first direction.

In addition, the first coupling slit 136 may be formed in a tapered shape in a mounting direction with the external bracket 300, thereby guiding the external bracket 300, and when installed on an outer wall, the first coupling slit 136 can be slidably coupled to the external bracket 300 so that it can be easily inserted even on the wall side, which is difficult for a worker to see. The second base 121 side end 137 of the first coupling slit 136 may be formed in a curved shape, so that the contact surface with the end of the external bracket 300 is widened. This allows the weight of the inverter module 200 to be fully transferred to the external bracket 300 during coupling. If the end of the first coupling slit 136 is formed sharply, the contact area with the end of the external bracket 300 becomes narrow, and thus the entire weight of the inverter module 200 may not be transferred to the external bracket 300 during coupling.

On one side of the first heat dissipation fin 131 adjacent to the first coupling slit 136, a coupling hole 138 for coupling with the external bracket 300 may be formed. After the inverter module 200 is mounted on the external bracket 300, it can be screw-coupled through the coupling hole 138 to be fixed to the external bracket 300.

Among the main heat dissipation fins, a second coupling slit having a shape corresponding to the first coupling slit 136 may be formed in the outermost main heat dissipation fin farthest from the first heat dissipation fin 131.

The second coupling slit may be formed inclined in a first direction towards a lower portion when the inverter module 200 is mounted on the external bracket 300, and may be formed in a tapered shape where the width of the slit widens. It may be formed inclined towards a lower portion so that it can receive force in a lower direction due to gravity when coupled with the external bracket 300. This allows for easier installation work by adding force in a coupling direction during the work, and can prevent the inverter module 200 from being detached after mounting.

In addition, the second coupling slit may be formed in a tapered shape in a mounting direction with the external bracket 300, thereby guiding the external bracket 300, and when installed on an outer wall, the second coupling slit can be easily inserted into the external bracket 300 even on the wall side, which is difficult for a worker to see. The end of the second coupling slit may be formed in a curved shape so that the contact surface with the end of the external bracket 300 is widened. This allows the weight of the inverter module 200 to be fully transferred to the external bracket 300 during coupling. If the end of the second coupling slit is formed sharply, the contact area with the end of the external bracket 300 becomes narrow, and thus the entire weight of the inverter module 200 may not be transferred to the external bracket 300 during coupling.

On one side of the main heat dissipation fin adjacent to the second coupling slit, a coupling hole for coupling with the external bracket 300 may be formed. After the inverter module 200 is mounted on the external bracket 300, it can be screw-coupled through the coupling hole to be fixed to the external bracket 300.

The external bracket 300 can be inserted into both the first coupling slit 136 and the second coupling slit, coupled, and fixed.

The main heat sink 220 and the inductor module 100 may be formed on one side of a lower portion of the case 210, and may include a coupling part 240 being extended to a lower portion of the case 210 on the opposite side to the side where the main heat sink 220 and the inductor module 100 are formed. The main heat sink 220 and the inductor module 100 may be formed to be protruded from a lower portion of the case 210. Since the main heat sink 220 and the inductor module 100 are eccentrically disposed on one side in a first case direction where the inverter driving part is disposed, when connected to the external bracket 300, the region where the main heat sink 220 and the inductor module 100 are not formed may be unstable due to being spaced apart from an outer wall and not being supported. At this position, the coupling part 240 is extended to the lower portion of the case 210 and can be coupled to an outer wall when installed on the external bracket 300, so that the inverter module 200 can be stably fixed. At this time, the extension length of the coupling part 240 may correspond to the length by which the lower portion of the case 210 is spaced apart from the wall surface when the inverter module 200 and the external bracket 300 are connected. In this way, the extension length is set, allowing the inverter module 200 to be fixed parallel to the wall surface, enabling stable operation. The coupling part 240 may be screw-coupled to the case 210 and may also be screw-coupled to the outer wall.

A space being separated from the wall surface may be formed between the main heat sink 220 and the inductor module 100 and the coupling part 240. The coupling part 240 may be disposed in a region of the lower portion of the case farthest from the main heat sink 220 and the inductor module 100. A region where the main heat sink 220 and the inductor module 100 and the coupling part 240 are not formed may be spaced apart from the outer wall, forming an empty space. Heat being discharged from the heat dissipation fin 130 of the main heat sink 220 and the inductor module 100 can be discharged into the separation space from the outer wall, and airflow can be generated in the separation space, enabling efficient heat dissipation.

The external bracket 300 may include a base 310, a first extension portion 320 being extended inclinedly from the base 310, a second extension portion 330, and a wing portion 340, and may include a coupling part 350. The inclined angle a of the first extension portion 320 may be between 50 and 80 degrees, for example, 65 degrees, to correspond to the angle at which the first coupling slit 136 is inclined with respect to the first direction. Or, it may be 45 degrees. The inclined angle of the wing portion 340 may be between 50 and 80 degrees.

As shown in FIG. 8, the external bracket 300 can be coupled with the first coupling slit 136. The external bracket 300 may include a base 310 and a first extension portion 321 being extended inclined from one end of the base 310 to correspond to the shape of the first coupling slit 136 and inserted into the first coupling slit 136, and a second extension portion 330 being extended from one end of the base 310 in a shape covering the outer surface of the outermost heat dissipation fin 134. Here, the first extension portion 321 and the second extension portion 330 may be vertically in contact. One side of the first extension portion 321 may be vertically in contact with the side of the second extension portion 330. The second extension portion 330 may include a wing portion 341 being extended inclined to the extension direction of the second extension portion 330. When the external bracket 300 and the inverter module 200 are coupled, the second extension portion contacts the outer surface of the outermost first heat dissipation fin 131, and the wing portion 341 may be extended inclined in a direction away from the outer surface of the outermost first heat dissipation fin 131. When the external bracket 300 and the inverter module 200 are coupled, the wing portion 341 can guide the outer surface of the outermost first heat dissipation fin 134 toward the first extension portion.

A coupling part 350 may be formed in the second extension portion 330 and screw-coupled with the coupling hole 138 of the first heat dissipation fin 131.

The external bracket 300 may include a first extension portion 322 being extended inclined from the other end of the base 310 to correspond to the shape of the second coupling slit and inserted into the second coupling slit, and a second extension portion 330 being extended from one end of the base 310 in a shape covering the outer surface of the outermost main heat dissipation fin. Here, the first extension portion 322 and the second extension portion 330 may be vertically in contact. One surface of the first extension portion 322 may be vertically in contact with a side surface of the second extension portion 330. The second extension portion 330 may include a wing portion 342 being extended inclined to the extension direction of the second extension portion. When the external bracket 300 and the inverter module 200 are coupled, the second extension portion contacts the outer surface of the outermost main heat dissipation fin, and the wing portion 342 may be extended inclined in a direction away from the outer surface of the outermost main heat dissipation fin. When the external bracket 300 and the inverter module 200 are coupled, the wing portion 342 can guide the outer surface of the outermost main heat dissipation fin toward the first extension portion.

A coupling part 350 may be formed in the second extension portion 330 and screw-coupled with the coupling hole of the main heat dissipation fin.

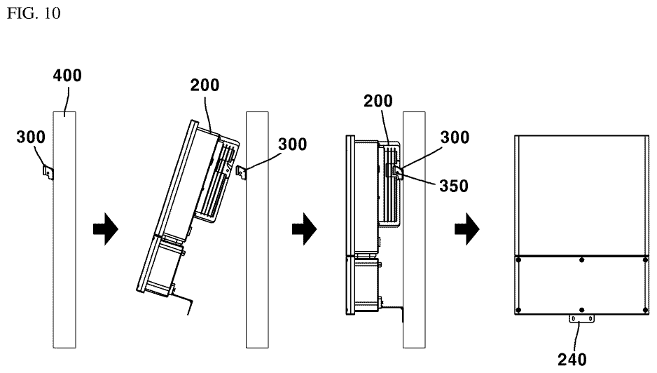

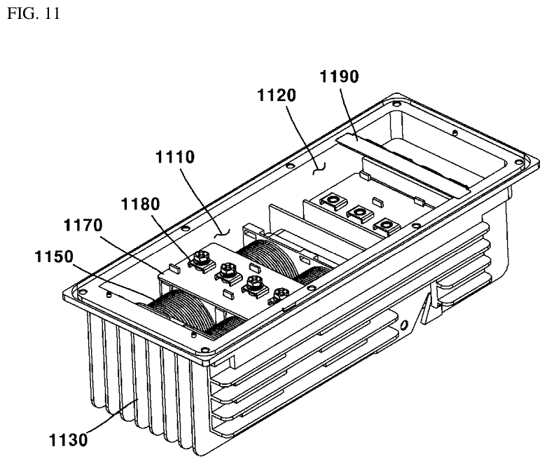

According to an embodiment of the present invention, the inverter module 200 can be installed on the external bracket 300 as shown in FIG. 10. First, the external bracket 300 is installed on the wall surface 400. Thereafter, the first extension portion 320 of the external bracket is seated into the first coupling slit and the second coupling slit of the inverter module 200, and after the coupling part 240 of the inverter module 200 is brought into close contact with the wall surface, bolts can be fastened through screw coupling to couple and fix the coupling part 350 of the external bracket 300 and the two positions on the wall surface.

Through this, the inverter module 200 can be installed with only one mounting bracket which is an external bracket.

An inductor module according to an embodiment of the present invention includes a first inductor and a second inductor, a first accommodating part forming a first internal space for accommodating the first inductor, and a second accommodating part forming a second internal space for accommodating the second inductor, wherein the first accommodating part and the second accommodating part may be formed spaced apart from each other. An inductor module according to an embodiment of the present invention may include a wire discharge portion from which wires being connected to the first inductor and the second inductor are drawn out, and a wire bracket for guiding the wires to the outside.

The wire discharge portion is extended from one side of the second side plate of the second accommodating part to form a passage through which wires pass, and the wire bracket can be disposed in the wire discharge portion to guide the wires. The wire bracket may include a base, a first extension portion being extended inclinedly from the base and including a through-hole through which one or more first wires being electrically connected to the first inductor and one or more second wires being electrically connected to the second inductor pass, and a second extension portion being extended parallel to the base from the first extension portion. The through-hole of the wire bracket may include a plurality of through-holes, and each of the plurality of through-holes may include a bushing portion having two holes being spaced apart from each other. Wires penetrating through the holes of the bushing portion can be inserted into the holes of the bushing portion, separated from other wires, and fixed in position for withdrawal to the wire discharge portion.

The first wire and the second wire can be introduced into a lower portion of the second extension portion, penetrate through the through-hole of the first extension portion, maintain a gap between them, and be drawn out to the wire discharge portion.

It includes a first inductor and a second inductor, a first accommodating part forming a first internal space for accommodating the first inductor, and a second accommodating part forming a second internal space for accommodating the second inductor, wherein the inductor module in which the first accommodating part and the second accommodating part are formed by being spaced apart from each other can be configured in various embodiments.

An inductor module according to an embodiment of the present invention can be implemented as shown in FIG. 11. A detailed description of each configuration of the inductor module according to an embodiment of FIG. 11 corresponds to the detailed description of the inductor module 100 of FIGS. 1 to 10, and any overlapping description will be briefly described hereinafter.

An inductor module according to an embodiment of the present invention includes a first inductor 1150 and a second inductor 1160, a first accommodating part 1110 forming a first internal space accommodating the first inductor 1150, and a second accommodating part 1120 forming a second internal space accommodating the second inductor 1160, wherein the first accommodating part 1110 and the second accommodating part 1120 may be formed to be spaced apart from each other. The first inductor 1150 may be an inverter-side inductor, and the second inductor 1160 may be a grid-side inductor.

The first accommodating part 1110 includes a first base 1111 and a first side plate 1112 being extended from the first base 1111, wherein the second accommodating part 1120 may include a second base 1121 and a second side plate 1122 being extended from the second base 1121. A separation space 1140 may be formed between the first accommodating part 1110 and the second accommodating part 1120.

The length from the first base 1111 of the first accommodating part 1110 to an upper end of the first accommodating part 1110 may be longer than the length from the second base 1121 of the second accommodating part 1120 to an upper end of the second accommodating part 1120.

The first inductor 1150 includes a plurality of coils 1151 and 1152, wherein the first base 1111 of the first accommodating part 1110 includes a first coil seating portion 1113 in which some of the plurality of coils are disposed and a second coil seating portion 1114 in which the remaining some of the plurality of coils are disposed, and wherein the first coil seating portion 1113 and the second coil seating portion 1114 may be formed to be spaced apart from each other. When a plurality of coils is disposed on one base, the positions of the coils are not fixed and may be unstable. The first base 1111 includes the first coil seating portion 1113 and the second coil seating portion 1114 so that the coils are seated and fixed at a set position.

The first inductor 1150 is disposed and molded in the first accommodating part 1110, and the second inductor 1160 may be disposed and molded in the second accommodating part 1120.

It includes the first substrate 1171 being connected to a lower portion and the terminal 1153 of the first inductor, and a first terminal block 1181 being disposed on an upper portion of the first substrate 1171 and connected to the first wire 1183. The first inductor 1150 may include a terminal block being exposed to the outside during molding to facilitate wire connection during molding. The first substrate 1171 may be disposed at a position corresponding to the position of the terminal 1153 of the first inductor.

The first terminal block 1181 and the terminal 1150 of the first inductor can be electrically connected. The first terminal block 1181 and the terminal 1153 of the first inductor can be electrically connected through the conductive pattern of the first substrate 1171.

The first terminal block 1181 may include: a third base 1186; a bolt accommodating part 1186 being extend from the center of the third base 1186 towards the lower portion and coupled through the first substrate 1171 to form an internal space for accommodating a bolt; and a coupling part 1187 being extend from the edge of the third base 1186 towards the lower portion and coupled to the first substrate 1171. The first terminal block 1181 is coupled to the first substrate 1171 through a coupling part 1187 being extend from the third base 1186, and may include a bolt accommodating part 1186 that forms an internal space for accommodating a bolt to prevent a hole into which a bolt is inserted from being filled with a molding liquid when connecting a wire to the first terminal block 1181 after molding. In addition, the bolt accommodating part 1186 may prevent a bolt 1189 being coupled for connection to a wire from being electrically connected to or affecting a coil of the first inductor 1150. The first terminal block 1181 may be coupled to a ring terminal 1188 of a first wire 1183 being disposed on the third base 1186 through the bolt 1189. The ring terminal 1188 connected to the end of the first wire 1183 can be fitted with a bolt 1189 and coupled together to the first terminal block 1181 to electrically connect the terminal of the coil of the first inductor 1150 and the first wire 1183.

When the first inductor 1150 is disposed on the first accommodating part 1110 and molded, the first substrate 1171 is molded, and the third base 1186 of the first terminal block 1181 may not be molded. The first substrate 1171 may be molded to allow heat dissipation, and the first terminal block may be exposed through an upper portion of the molding to be coupled with the first wire 1183.

It includes: a second substrate 1172 in which a terminal of the second inductor and a lower portion thereof are connected; and a second terminal block 1182 being connected with the second wire 1184, wherein the second terminal block 1182 and the terminal 1161 of the second inductor can be electrically connected. The second terminal block 1182 may be formed in the same shape as the first terminal block 1181.

The second terminal block 1182 may include: a third base 1186; a bolt accommodating part 1186 being extended from the center of the third base 1186 towards the lower portion and coupled through the second substrate 1172 to form an internal space for accommodating a bolt; and a coupling part 1187 being extended from the edge of the third base 1186 towards the lower portion and coupled to the second substrate 1172. The second terminal block 1182 may be coupled to the second substrate 1172 through the coupling part 1187 being extended from the third base 1186, and may include a bolt accommodating part 1186 forming an internal space for accommodating a bolt to prevent the hole for bolt insertion from being filled with molding liquid when connecting wires to the second terminal block 1182 after molding. In addition, the bolt accommodating part 1186 can prevent the bolt 1189 being coupled for wire connection from being electrically connected to or affecting the coil of the second inductor 1160. The second terminal block 1182 can be coupled via a ring terminal 1188 of the second wire 1184 being disposed on the third base 1186 and a bolt 1189. The ring terminal 1188 being connected to the end of the second wire 1184 can be fitted with a bolt 1189 and coupled together to the second terminal block 1182 to electrically connect the terminal of the coil of the second inductor 1160 and the second wire 1184.

When the second inductor 1160 is disposed in the second accommodating part 1120 and molded, the second substrate 1172 may be molded, and the third base 1186 of the second terminal block 1182 may not be molded. The second substrate 1172 may be molded to allow heat dissipation, and the second terminal block may be exposed through the upper portion of the molding to be coupled with the second wire 1184.

When one or more first wires 1183 electrically connected to the first inductor 1150 and one or more second wires 1184 being electrically connected to the second inductor 1160 are drawn outside the inductor module, a wire bracket may be used. By using the wire bracket, the gap between the wires can be maintained, the position can be fixed, and workability can be improved.

It may include a wire discharge portion 1125 being extended from one side of the second side plate 1122 of the second accommodating part 1120 to form a passage through which a wire passes, and may include a first wire bracket 1190 being disposed in the wire discharge portion 1125. The first wire bracket 1190 may include a fifth base 1191 being in contact with the fourth base 1124 of the wire discharge portion 1125, a first extension portion 1192 being extended obliquely from the fifth base 1191 and includes a first through-hole 1194 through which one or more first wires 1183 electrically connected to the first inductor 1150 and one or more second wires 1184 electrically connected to the second inductor 1160 penetrate, and a second extension portion 1193 being extended parallel to the fifth base 1191 from the first extension portion 1192. A coupling hole 1196 may be formed in the fifth base 1191 so as to be coupled with the fourth base 1124. The fifth base 1191 can be fixedly connected to the fourth base 1124 through the coupling hole 1196.

To guide the withdrawal of the wire, a first through-hole may be formed, wherein the first through-hole 1194 includes a plurality of first through-holes, and each of the plurality of first through-holes may include a first bushing portion 1195 including two holes being spaced apart from each other.

The wire is introduced into the lower portion of the second extension portion 1193, penetrates through the hole of the first bushing portion 1195 included in the first through-hole 1194, is introduced into the wire discharge portion 1125, and can be drawn out to the outside of the inductor module through an open space exposed upward.

When the inductor module is mounted on the inverter module, it is bonded to the heat dissipation plate 1221 of the main heat sink of the inverter module, and a wire discharge portion 1222 is formed in the heat dissipation plate 1221 through which the wire of the inductor module is discharged, so that the wire can be drawn into the case of the inverter module through the wire discharge portion 1125 of the heat dissipation plate 1221.

An inductor module according to an embodiment of the present invention can be implemented as shown in FIG. 21. A detailed description of each configuration of the inductor module according to the embodiment of FIG. 21 corresponds to the detailed description of the inductor module 100 of FIGS. 1 to 10, and any overlapping description will be briefly described hereinafter.

An inductor module according to an embodiment of the present invention includes a first inductor 2150 and a second inductor 2160, a first accommodating part 2110 forming a first internal space accommodating the first inductor 2150, and a second accommodating part 2120 forming a second internal space accommodating the second inductor 2160, wherein the first accommodating part 2110 and the second accommodating part 2120 may be formed to be spaced apart from each other. The first inductor 2150 may be an inverter-side inductor, and the second inductor 2160 may be a grid-side inductor.

The first accommodating part 2110 may include a first base 2111 and a first side plate 2112 being extended from the first base 2111, and the second accommodating part 2120 may include a second base 2121 and a second side plate 2122 being extended from the second base 2121. A separation space 2140 may be formed between the first accommodating part 2110 and the second accommodating part 2120.

The length from the first base 2111 of the first accommodating part 2110 to an upper end of the first accommodating part 2110 may be longer than the length from the second base 2121 of the second accommodating part 2120 to an upper end of the second accommodating part 2120.

The first inductor 2150 may include a plurality of coils 2151 and 2152 and may include a coil fixing part surrounding the coils. The position may be fixed by the coil fixing part. The first inductor 2150 may be disposed in the first accommodating part 2110 and molded, and the second inductor 2160 may include a plurality of coils 2161 and 2162 and may be disposed in the second accommodating part 2120 and molded.

When one or more first wires being electrically connected to the first inductor 2150 and one or more second wires being electrically connected to the second inductor 2160 are withdrawn outside the inductor module, a wire bracket may be used. By using the wire bracket, a gap between the wires can be maintained, its position can be fixed, and workability can be improved. The configuration of the wire bracket of the inductor module according to the embodiment of FIG. 21 corresponds to the detailed description of the wire bracket of FIGS. 18 to 20 except for the configuration of the second extension portion 2193, and thus, any overlapping description will be briefly described.

It may include a wire discharge portion being extended from one side of the second side plate 2122 of the second accommodating part 2120 to form a passage through which a wire passes, and may include a first wire bracket 2190 being disposed in the wire discharge portion. The first wire bracket 2190 may include a fifth base being in contact with the fourth base of the wire discharge portion, a first extension portion being extended obliquely from the fifth base and includes a first through-hole through which one or more first wires electrically connected to the first inductor 2150 and one or more second wires electrically connected to the second inductor 2160 penetrate, and a second extension portion 2193 being extended parallel to the fifth base from the first extension portion. Here, a hole is formed in the second extension portion 330 so that the worker can improve workability when connecting wires. A coupling hole can be formed in the fifth base so that it can be coupled with the fourth base. The fifth base can be coupled and fixed to the fourth base through the coupling hole.

To guide the withdrawal of the wire, a first through-hole may be formed, wherein the first through-hole includes a plurality of first through-holes, and each of the plurality of first through-holes may include a first bushing portion including two holes being spaced apart from each other.

The wire is introduced into the lower portion of the second extension portion, penetrates through the hole of the first bushing portion included in the first through-hole, is introduced into the wire discharge portion, and can be drawn out to the outside of the inductor module through an open space exposed upward.

When the inductor module is mounted on the inverter module, it is bonded to the heat dissipation plate 1221 of the main heat sink of the inverter module, and a wire discharge portion 1222 is formed in the heat dissipation plate 1221 through which the wire of the inductor module is discharged, so that the wire can be drawn into the case of the inverter module through the wire discharge portion 1125 of the heat dissipation plate 1221.

An inductor module according to an embodiment of the present invention can be implemented as shown in FIG. 24. A detailed description of each configuration of the inductor module according to the embodiment of FIG. 24 corresponds to the detailed description of the inductor module 100 of FIGS. 1 to 10, and any overlapping description will be briefly described hereinafter.

An inductor module according to an embodiment of the present invention includes a first inductor 3150 and a second inductor 3160, a first accommodating part 3110 forming a first internal space accommodating the first inductor 3150, and a second accommodating part 3120 forming a second internal space accommodating the second inductor 3160, wherein the first accommodating part 3110 and the second accommodating part 3120 may be formed to be spaced apart from each other. The first inductor 3150 may be an inverter-side inductor, and the second inductor 3160 may be a grid-side inductor.

The first accommodating part 3110 includes a first base 3111 and a first side plate 3112 being extended from the first base 3111, wherein the second accommodating part 3120 may include a second base 3121 and a second side plate 3122 being extended from the second base 3121. A separation space 3140 may be formed between the first accommodating part 3110 and the second accommodating part 3120.

The length from the first base 3111 of the first accommodating part 3110 to an upper end of the first accommodating part 3110 may be longer than the length from the second base 3121 of the second accommodating part 3120 to an upper end of the second accommodating part 3120.

The first inductor 3150 includes a plurality of coils 3151 and 3152, wherein the first base 3111 of the first accommodating part 3110 includes a first coil seating portion 3113 in which some of the plurality of coils are disposed and a second coil seating portion 3114 in which the remaining some of the plurality of coils are disposed, and wherein the first coil seating portion 3113 and the second coil seating portion 3114 may be formed to be spaced apart from each other. When a plurality of coils is disposed on one base, the positions of the coils are not fixed and may be unstable. The first base 3111 includes the first coil seating portion 3113 and the second coil seating portion 3114 so that the coils are seated and fixed at a set position.

The first inductor 3150 may include a plurality of coils 3151 and 3152, and may include a coil fixing part that contacts the first base 3111 and includes a coil penetration part penetrating the coils 3151 and 3152 to fix the position of the coils. The position may be fixed by the coil fixing part. The first inductor 3150 may be disposed in the first accommodating part 3110 and molded, and the second inductor 3160 may include a plurality of coils 3161 and 3162 and may be disposed in the second accommodating part 3120 and molded.

When the plurality of coils 3151 and 3152 of the first inductor 3150 are disposed and molded in the first accommodating part 3110, a portion of the plurality of first wires, each electrically connected to a terminal of the plurality of coils 3151 and 3152, is also molded, and at least a portion of each of the plurality of coils is exposed to the outside of the molding, and the first wires can be drawn out toward the second accommodating part 3120 by passing between the coils being exposed to the outside of the molding.

When one or more first wires being electrically connected to the first inductor 3150 and one or more second wires being electrically connected to the second inductor 3160 are withdrawn outside the inductor module, a wire bracket may be used. By using the wire bracket, a gap between the wires can be maintained, its position can be fixed, and workability can be improved. The configuration of the wire bracket of the inductor module according to the embodiment of FIG. 24 corresponds to the detailed description of the wire bracket of FIGS. 18 to 20 and the wire bracket of the inductor module according to the embodiment of FIG. 21, and thus, any overlapping description will be briefly described.

It may include a wire discharge portion being extended from one side of the second side plate 3122 of the second accommodating part 3120 to form a passage through which a wire passes, and may include a first wire bracket 3190 being disposed in the wire discharge portion. The first wire bracket 3190 may include a fifth base being in contact with the fourth base of the wire discharge portion, a first extension portion being extended obliquely from the fifth base and includes a first through-hole through which one or more first wires electrically connected to the first inductor 3150 and one or more second wires electrically connected to the second inductor 3160 penetrate, and a second extension portion being extended parallel to the fifth base from the first extension portion. Here, a hole is formed in the second extension portion so that the worker can improve workability when connecting wires. A coupling hole can be formed in the fifth base so that it can be coupled with the fourth base. The fifth base can be coupled and fixed to the fourth base through the coupling hole.

To guide the withdrawal of the wire, a first through-hole may be formed, wherein the first through-hole includes a plurality of first through-holes, and each of the plurality of first through-holes may include a first bushing portion including two holes being spaced apart from each other.

The wire is introduced into the lower portion of the second extension portion, penetrates through the hole of the first bushing portion included in the first through-hole, is introduced into the wire discharge portion, and can be drawn out to the outside of the inductor module through an open space exposed upward.

When the inductor module is mounted on the inverter module, it is bonded to the heat dissipation plate 1221 of the main heat sink of the inverter module, and a wire discharge portion 1222 is formed in the heat dissipation plate 1221 through which the wire of the inductor module is discharged, so that the wire can be drawn into the case of the inverter module through the wire discharge portion 1125 of the heat dissipation plate 1221.

An inductor module according to an embodiment of the present invention can be implemented as shown in FIG. 27. A detailed description of each configuration of the inductor module according to an embodiment of FIG. 27 corresponds to the detailed description of the inductor module 100 of FIGS. 1 to 10, and any overlapping description will be briefly described hereinafter.

An inductor module according to an embodiment of the present invention includes a first inductor 4150 and a second inductor 4160, a first accommodating part 4110 forming a first internal space accommodating the first inductor 4150, and a second accommodating part 4120 forming a second internal space accommodating the second inductor 4160, wherein the first accommodating part 4110 and the second accommodating part 4120 may be formed to be spaced apart from each other. The first inductor 4150 may be an inverter-side inductor, and the second inductor 4160 may be a grid-side inductor.

The first accommodating part 4110 includes a first base 4111 and a first side plate 4112 being extended from the first base 4111, wherein the second accommodating part 4120 may include a second base 4121 and a second side plate 4122 being extended from the second base 4121. A separation space 4140 may be formed between the first accommodating part 4110 and the second accommodating part 4120.

The length from the first base 4111 of the first accommodating part 4110 to an upper end of the first accommodating part 4110 may be longer than the length from the second base 4121 of the second accommodating part 4120 to an upper end of the second accommodating part 4120.

The first inductor 4150 may include a plurality of coils 4151 and 4152 and may include a coil fixing part surrounding the coils. The position may be fixed by the coil fixing part. The first inductor 4150 may be disposed in the first accommodating part 4110 and molded, and the second inductor 4160 may include a plurality of coils 4161 and 4162 and may be disposed in the second accommodating part 4120 and molded.

When one or more first wires being electrically connected to the first inductor 4150 and one or more second wires being electrically connected to the second inductor 4160 are withdrawn outside the inductor module, a wire bracket may be used. By using the wire bracket, a gap between the wires can be maintained, its position can be fixed, and workability can be improved. The configuration of the wire bracket of the inductor module according to the embodiment of FIG. 21 corresponds to the detailed description of the wire bracket of FIGS. 18 to 20 except for the configuration of the second wire bracket 4290, and any overlapping description will be briefly explained.

The height of the side plate of the first accommodating part may extend to the uppermost end of the inductor module, and the entire first accommodating part may be molded 4115. In order to withdraw the wire from the molded first accommodating part, a second wire bracket 4290 may be included in a space between the first accommodating part and the second accommodating part. The second wire bracket 4290 may include: a sixth base being disposed in the space between the first accommodating part and the second accommodating part; a third side plate being extended from the sixth base; and a second through-hole through which a plurality of first wires, each of which is electrically connected to each terminal of a plurality of coils, penetrates, in the third side plate adjacent to the first accommodating part among the third side plates. The second through-hole may include a first bushing portion including a plurality of second through-holes, wherein each of the plurality of second through-holes includes two holes being spaced apart from each other.

The height of the third side plate adjacent to the first accommodating part among the third side plates may be higher than the height of the third side plate adjacent to the second accommodating part among the third side plates. The third side plate adjacent to the first accommodating part may be formed at a height at which the first accommodating part is molded 4115, and the third side plate adjacent to the second accommodating part may be formed at a height at which the second accommodating part is molded 4123.

A second accommodating part 4120 may include a wire discharge portion being extended from one side of a second side plate 4122 to form a passage through which a wire passes, and may include a first wire bracket 4190 being disposed in the wire discharge portion. The wire bracket 4190 may include: a fifth base being in contact with a fourth base of the wire discharge portion; a first extension portion being extended obliquely from the fifth base and including a first through-hole through which at least one first wire being electrically connected to the first inductor 4150 and at least one second wire being electrically connected to the second inductor 4160 penetrates; and a second extension portion 4193 being extended parallel to the fifth base from the first extension portion. A coupling hole may be formed in the fifth base so as to be coupled with the fourth base. The fifth base may be coupled to and fixed to the fourth base through the coupling hole.

The wire is introduced into the lower portion of the second extension portion, penetrates through the hole of the first bushing portion included in the first through-hole, is introduced into the wire discharge portion, and can be drawn out to the outside of the inductor module through an open space exposed upward.

When the inductor module is mounted on the inverter module, it is bonded to the heat dissipation plate 1221 of the main heat sink of the inverter module, and a wire discharge portion 1222 is formed in the heat dissipation plate 1221 through which the wire of the inductor module is discharged, so that the wire can be drawn into the case of the inverter module through the wire discharge portion 1125 of the heat dissipation plate 1221.

An inductor module according to an embodiment of the present invention can be implemented as shown in FIG. 30. A detailed description of each configuration of the inductor module according to an embodiment of FIG. 27 corresponds to the detailed description of the inductor module 100 of FIGS. 1 to 10, and any overlapping description will be briefly described hereinafter.

An inductor module according to an embodiment of the present invention includes a first inductor 3150 and a second inductor 3160, a first accommodating part 3110 forming a first internal space accommodating the first inductor 3150, and a second accommodating part 3120 forming a second internal space accommodating the second inductor 3160, wherein the first accommodating part 3110 and the second accommodating part 3120 may be formed to be spaced apart from each other. The first inductor 3150 may be an inverter-side inductor, and the second inductor 3160 may be a grid-side inductor.

The inductor module according to the embodiment of FIG. 30 may include a first accommodating part in which a first inductor 150 is disposed in the direction in which a wire is discharged, and a second accommodating part in which a second inductor 160 is disposed in an opposite direction to the direction in which the wire is discharged.

The first accommodating part 5110 includes a first base 5111 and a first side plate 5112 being extended from the first base 5111, wherein the second accommodating part 5120 may include a second base 5121 and a second side plate 5122 being extended from the second base 5121. A separation space may be formed between the first accommodating part 5110 and the second accommodating part 5120.

The sizes of the coils 5151 and 5152 of the first inductor 150 and the coil 5161 of the second inductor 160 may be the same. Accordingly, the length from the first base 5111 of the first accommodating part 5110 to the upper end of the first accommodating part 5110 may be the same as the length from the second base 5121 of the second accommodating part 5120 to the upper end of the second accommodating part 5120.

The first inductor 5150 may include a plurality of coils 5151 and 5152, and may include a coil fixing part that contacts the first base 5111 and includes a coil penetration part penetrating the coils 5151 and 5152 to fix the position of the coils. The position may be fixed by the coil fixing part. The first inductor 5150 may be disposed in the first accommodating part 5110 and molded 5115, and the second inductor 5160 may include a plurality of coils 5161 and 5162 and may be disposed in the second accommodating part 5120 and molded 5123.

When one or more first wires being electrically connected to the first inductor 5150 and one or more second wires being electrically connected to the second inductor 5160 are withdrawn outside the inductor module, a wire bracket may be used. By using the wire bracket, a gap between the wires can be maintained, its position can be fixed, and workability can be improved.

The height of the side plate of the first accommodating part may extend to the uppermost end of the inductor module, and the entire first accommodating part is molded 5115, the height of the side plate of the second accommodating part may extend to the uppermost end of the inductor module, and the entire second accommodating part may be molded 5123. In order to withdraw the second wire from the molded second accommodating part, a third wire bracket 5290 may be included in the space between the first accommodating part and the second accommodating part.

A third wire bracket 5290 includes a seventh base being disposed in a space between the first accommodating part and the second accommodating part, a fourth side plate being extended from the seventh base, a third through-hole through which a plurality of second wires, each of which is electrically connected to each terminal of a plurality of coils, penetrates through a fourth side plate among the fourth side plates adjacent to the second accommodating part, and a fourth through-hole through which a plurality of second wires penetrates through a fourth side plate among the fourth side plates adjacent to the first accommodating part. The height of the fourth side plate among the fourth side plates adjacent to the first accommodating part may be the same as a height of the fourth side plate among the fourth side plates adjacent to the second accommodating part. Since both the first accommodating part and the second accommodating part are molded up to an upper portion, it may include a first bushing portion including through-holes on both sides, wherein each through-hole includes two holes spaced apart from each other.

A wire discharge portion being extended from one side of a side plate of the first accommodating part to form a passage through which a wire passes is included, and a fourth wire bracket 5190 being disposed in the wire discharge portion may be included. The fourth wire bracket 5190 may include a ninth base being in contact with the eighth base of the wire discharge portion, and a fifth side plate being extended from the ninth base and including a fifth through-hole through which at least one first wire being electrically connected to the first inductor 5150 and at least one second wire being electrically connected to the second inductor 5160 penetrates.

The first wire and the second wire are introduced into the wire discharge portion through the fourth wire bracket 5190 and drawn out to the outside of the inductor module through the open space exposed upward.

When the inductor module is mounted on the inverter module, it is bonded to the heat dissipation plate 1221 of the main heat sink of the inverter module, and a wire discharge portion 1222 is formed in the heat dissipation plate 1221 through which the wire of the inductor module is discharged, so that the wire can be drawn into the case of the inverter module through the wire discharge portion 1125 of the heat dissipation plate 1221.

By configuring the inductor module as described above, the inductor that generates a lot of heat can be efficiently dissipated, and the wire connected to the inductor module can be efficiently withdrawn into the case of the inverter module.

An inverter module according to an embodiment of the present invention includes a case 210 forming an internal space in which components are disposed, a main heat sink 220 including a heat dissipation plate being coupled to a lower portion of the case 210 and a main heat dissipation fin being extended from the heat dissipation plate, and an inductor module bonded and coupled to a region of the lower portion of the heat dissipation plate of the main heat sink 220 in which the main heat dissipation fin is not formed, and in which an inductor is disposed in the internal space. The inductor module may include one of the inductor modules according to the embodiments of FIGS. 11 to 32. A detailed description of each inductor module corresponds to the detailed description of the inductor module of FIGS. 11 to 32, and thus, any overlapping description will be omitted below.

The main heat dissipation plate includes a wire discharge portion 1125 from which a plurality of wires being electrically connected to the inductor module are discharged, and the plurality of wires being discharged from the wire discharge portion 1125 can be guided to positions corresponding to positions of the connectors to which they are respectively connected and discharged. When a worker performs the task of connecting wires whose positions are guided to connectors, workability can be improved.

Although the present invention has been described with specific details such as specific components and limited examples and drawings, these have been provided only to help a more general understanding of the present invention, and the present invention is not limited to the above examples, and those with common knowledge in the field to which the present invention belongs can make various modifications and variations from this description.

Therefore, the idea of the present invention should not be limited to the described embodiments, and all things that are equivalent or equivalent to the claims described below as well as the claims are included in the scope of the idea of the present invention.

1. An inductor module comprising:
a first inductor and a second inductor;
a first accommodating part forming a first internal space accommodating the first inductor; and
a second accommodating part forming a second internal space accommodating the second inductor,
wherein the first accommodating part and the second accommodating part are formed to be spaced apart from each other.

2. An inductor module according to claim 1,
wherein the accommodating part comprises:
a first base; and
a first side plate extended from the first base,
wherein the second accommodating part comprises:
a second base; and
a second side plate extended from the second base, and
wherein a length from the first base of the first accommodating part to an upper end of the first accommodating part is longer than a length from the second base of the second accommodating part to an upper end of the second accommodating part.

3. The inductor module according to claim 2,
wherein the first inductor comprises a plurality of coils,
wherein the first base of the first accommodating part comprises:
a first coil seating portion on which some of the plurality of coils are disposed; and
a second coil seating portion on which others of the plurality of coils are disposed, and
wherein the first coil seating portion and the second coil seating portion are formed to be spaced apart from each other.

4. The inductor module according to claim 1,
wherein the first inductor is disposed in the first accommodating part and molded, and
wherein the second inductor is disposed in the second accommodating part and molded.

5. The inductor module according to claim 1, comprising:
a first substrate whose a lower portion is connected with a terminal of the first inductor; and
a first terminal block disposed on an upper portion of the first substrate to be connected to a first wire,
wherein the first terminal block and the terminal of the first inductor are electrically connected.

6. The inductor module according to claim 5,
wherein the first terminal block and the terminal of the first inductor are electrically connected through a conductive pattern of the first substrate.

7. The inductor module according to claim 5,
wherein the first terminal block comprises:
a third base;
a bolt accommodating part extended from a center of the third base in a lower direction, coupled through the first substrate, and forming an internal space for accommodating a bolt; and
a coupling part extended from an edge of the third base in a lower direction and coupled with the first substrate, and
wherein the first terminal block is coupled with a ring terminal of the first wire disposed on the third base through the bolt.

8. The inductor module according to claim 7,
wherein when the first inductor is disposed in the first accommodating part and molded, the first substrate is molded and the third base of the first terminal block is not molded.

9. The inductor module according to claim 1, comprising:
a second substrate whose a lower portion is connected with a terminal of the second inductor; and
a second terminal block disposed on an upper portion of the second substrate to be connected to a second wire,
wherein the second terminal block and the terminal of the second inductor are electrically connected.

10. An inductor module according to claim 1, comprising:
a wire discharge portion extended from one side of a second side plate of the second accommodating part to form a passage through which a wire passes; and
a first wire bracket disposed on the wire discharge portion,
wherein the first wire bracket comprises:
a fifth base in contact with a fourth base of the wire discharge portion;
a first extension portion extended slantingly from the fifth base and comprising a first through-hole through which at least one first wire electrically connected to the first inductor and at least one second wire electrically connected to the second inductor penetrate; and
a second extension portion extended from the first extension portion in parallel with the fifth base.

11. The inductor module according to claim 10,
wherein the first through-hole comprises a plurality of first through-holes, and
wherein each of the plurality of first through-holes comprising a first bushing portion comprising two holes spaced apart from each other.

12. The inductor module according to claim 1,
wherein the first inductor is an inverter-side inductor, and the second inductor is a grid-side inductor.

13. The inductor module according to claim 2, comprising:
a second wire bracket in a space between the first accommodating part and the second accommodating part,
wherein the first inductor comprises a plurality of coils,
wherein the second wire bracket comprises:
a sixth base disposed in the space between the first accommodating part and the second accommodating part;
a third side plate extended from the sixth base; and
a second through-hole through which a plurality of first wires, each electrically connected to each terminal of the plurality of coils, penetrate the third side plate adjacent to the first accommodating part among the third side plates.

14. The inductor module according to claim 13,
wherein a height of the third side plate adjacent to the first accommodating part among the third side plates is higher than a height of the third side plate adjacent to the second accommodating part among the third side plates.

15. The inductor module according to claim 2, comprising:
a third wire bracket in a space between the first accommodating part and the second accommodating part,
wherein the second inductor comprises a plurality of coils,
wherein the third wire bracket comprises:
a seventh base disposed in the space between the first accommodating part and the second accommodating part;
a fourth side plate extended from the seventh base;
a third through-hole, in a fourth side plate among the fourth side plates adjacent to the second accommodating part, through which a plurality of second wires, each of which is electrically connected to each terminal of the plurality of coils, penetrate; and
a fourth through-hole, in a fourth side plate among the fourth side plates adjacent to the first accommodating part, through which the plurality of second wires penetrate.

16. The inductor module according to claim 15,
wherein a height of the fourth side plate adjacent to the first accommodating part among the fourth side plates is same as a height of the fourth side plate adjacent to the second accommodating part among the fourth side plates.

17. The inductor module according to claim 15, comprising:
a wire discharge portion extended from one side of the side plate of the first accommodating part to form a passage through which a wire passes; and
a fourth wire bracket disposed in the wire discharge portion,
wherein the fourth wire bracket comprises:
a ninth base in contact with the eighth base of the wire discharge portion; and
a fifth side plate extended from the ninth base and comprising a fifth through-hole through which at least one first wire electrically connected to the first inductor and at least one second wire electrically connected to the second inductor penetrate.

18. The inductor module according to claim 2,
wherein the first inductor comprises a plurality of coils,
wherein when the plurality of coils are disposed and molded in the first accommodating part, a portion of a plurality of first wires each electrically connected to each terminal of the plurality of coils is also molded,
wherein at least a portion of each of the plurality of coils is exposed to the outside of the molding, and
wherein the first wire passes between the coils exposed to the outside of the molding and is extended toward the second accommodating part.

19. An inverter module comprising:
a case forming an internal space in which components are placed;
a main heat sink comprising a heat dissipation plate coupled to a lower portion of the case and a main heat dissipation fin extended from the heat dissipation plate; and
an inductor module bond-coupled to a region of a lower region of the heat dissipation plate of the main heat sink which is not formed with the main heat dissipation fin and disposed with an inductor in an internal space thereof,
wherein the inductor module comprises:
a first accommodating part forming a first internal space accommodating the first inductor; and
a second accommodating part forming a second internal space accommodating the second inductor,
wherein the first accommodating part and the second accommodating part are formed to be spaced apart from each other.

20. The inverter module according to claim 19,
wherein the main heat dissipation plate comprises a wire discharge portion from which a plurality of wires electrically connected to the inductor module are discharged,
wherein the plurality of wires discharged from the wire discharge portion is guided and discharged to positions corresponding to positions of connectors respectively connected thereto.
